(19) United States
(12) Patent Application Publication
(10) Pub. No.: US 2020/0211821 A1
(43) Pub. Date: Jul. 2, 2020

(54) ELECTRON BEAM IRRADIATION DEVICE

(71) Applicant: KABUSHIKI KAISHA SENRYOU, Toyama-shi (JP)

(72) Inventor: Makoto YASUKAGAWA, Natori-shi (JP)

(73) Assignee: KABUSHIKI KAISHA SENRYOU, Toyama-shi (JP)

(21) Appl. No.: 16/675,353

(22) Filed: Nov. 6, 2019

(30) Foreign Application Priority Data
Dec. 26, 2018 (JP) 2018-242052

(51) Int. Cl. H01J 37/30; H01J 37/06

(52) U.S. Cl. CPC H01J 37/3002; H01J 2237/006; H01J 2237/0473; H01J 37/06

(57) ABSTRACT

An electron beam irradiation device that can irradiate an object in water with an electron beam is provided. An acceleration tube 11 includes an acceleration space 21 in which an electron beam generated by an electron gun 12 is accelerated and an irradiation port 22 through which the electron beam accelerated in the acceleration space 21 can be irradiated to the outside. Hydrogen gas 32 supply means 13 can supply the acceleration space 21 with hydrogen gas 32 at a predetermined pressure. The hydrogen gas 32 supplied to the acceleration space 21 by the hydrogen gas 32 supply means 13 is emitted from the irradiation port 22 and the electron beam irradiated from the irradiation port 22 passes through the hydrogen gas 32 emitted from the irradiation port 22.

### FIELD OF THE INVENTION

The present invention relates to an electron beam irradiation device.

### DESCRIPTION OF RELATED ART

In the prior art, a typical electron beam irradiation device includes an electron beam source such an electron gun that generates an electron beam, and an acceleration tube used to accelerate the generated electron beam (see, for example, Patent Literature 1). A device that uses an electron beam to produce plasma used in dry etching and other methods has also been developed (see, for example, Non-patent Literature 1 or 2).

### CITATION LIST

Patent Literature 1: JP-A-2005331418
Non-patent Literature 1: T. Hara (1993), Plasma Production by Electron Beam, Journal of Plasma and Fusion Research, Vol. 69, No. 6, pp. 647 to 655
Non-patent Literature 2: T. Hara (1992), Development of Electron-beam-excited Plasma Etching Device, Riken News, No. 132, pp. 1 to 5

### SUMMARY OF THE INVENTION

With a conventional electron beam irradiation device such as that described in Patent Literature 1, Non-patent Literature 1 and 2, an object in water cannot be irradiated with an electron beam because an electron beam (electron ray) cannot easily pass through water.

The present invention has been developed focusing on the-above described problem, and it is an object of the present invention to provide an electron beam irradiation device that can irradiate an object in water with an electron beam.

In order to achieve the above object, an electron beam irradiation device according to the present invention includes an electron gun that generates an electron beam; an acceleration tube including an acceleration space provided for accelerating the electron beam generated by the electron gun, and an irradiation port that can irradiate the electron beam accelerated in the acceleration space to the outside; and hydrogen gas supply means configured to supply the acceleration space with hydrogen gas at a predetermined pressure, in which the hydrogen gas supplied to the acceleration space by the hydrogen gas supply means is emitted from the irradiation port, and the electron beam irradiated from the irradiation port passes through the hydrogen gas emitted from the irradiation port.

In the electron beam irradiation device according to the present invention, among the hydrogen gas supplied to the acceleration space by the hydrogen gas supply means, the electron beam generated by the electron gun and accelerated in the acceleration space of the acceleration tube can be used to successively ionize and make into plasma the hydrogen gas present at a portion through which the electron beam passes. The produced plasma is continuously irradiated with the electron beam to heat the plasma. Therefore, under the same pressure, the plasma can be expanded and density of the plasma can be reduced. With this configuration, it is possible to lengthen the distance through which the electron beam can pass in inverse proportion to density of the plasma.

In the electron beam irradiation device according to the present invention, the same applies outside the acceleration space, in that the electron beam passes through the hydrogen gas emitted to the outside from the irradiation port, and hence the hydrogen gas present where the electron beam passes can be ionized and made into plasma. Therefore, the plasma can be continuously irradiated with the electron beam to heat and expand the plasma and facilitate passage of the electron beam. Thus, the electron beam irradiation device according to the present invention can irradiate an electron beam toward an object external to the irradiation port.

In the electron beam irradiation device according to the present invention, secondary electrons are generated when turning the hydrogen gas into plasma and these secondary electrons can also accelerate with the electron beam. Because hydrogen gas constantly flows ahead of the electron beam, a secondary electron avalanche occurs and the electron beam can be irradiated with a large current. Protons generated when turning the hydrogen gas into plasma come into contact with the inner walls of the acceleration space and other components to receive electrons and return to the hydrogen gas.

The electron beam irradiation device according to the present invention is preferably configured such that, when the irradiation port is placed in water, the hydrogen gas can be emitted toward an object placed at a predetermined position in the water and the object can be irradiated with the electron beam. With this configuration, an object placed in water can be irradiated with an electron beam. In other words, with the electron beam irradiation device according to the present invention, hydrogen gas can be emitted within water from the irradiation port by setting the pressure of hydrogen gas supplied to the acceleration space by the hydrogen gas supply means to more than or equal to the pressure of water outside the irradiation port. As a result, hydrogen gas is emitted toward the object placed in the water, the electron beam passes through the hydrogen gas, and thus the object can be irradiated with the electron beam.

When adopting such a configuration, the electron beam irradiation device may include current generation means that can generate a current. In addition, an object that is a liquid, a gas or plasma may be trapped at the predetermined position in the water by the current generated by the current generation means. As a result, even an object that is a liquid, a gas or plasma can be irradiated with an electron beam without being dispersed in the water.

According to the present invention, there can be provided an electron beam irradiation device that can irradiate an object in water with an electron beam.

### BRIEF DESCRIPTION OF THE DRAWINGS

FIG. 1 is a longitudinal cross-sectional diagram for illustrating an electron beam irradiation device according to an embodiment of the present invention.

FIG. 2 is a longitudinal cross-sectional diagram for illustrating a modification example of the electron beam irradiation device illustrated in FIG. 1 when the electron beam irradiation device is used in water.

FIG. 3 is a longitudinal cross-sectional diagram for illustrating the electron beam irradiation device illustrated in FIG. 2 when the electron beam irradiation device is used to generate nuclear fusion power.

### DETAILED DESCRIPTION OF THE INVENTION

Embodiments of the present invention are described below with reference to the drawings.

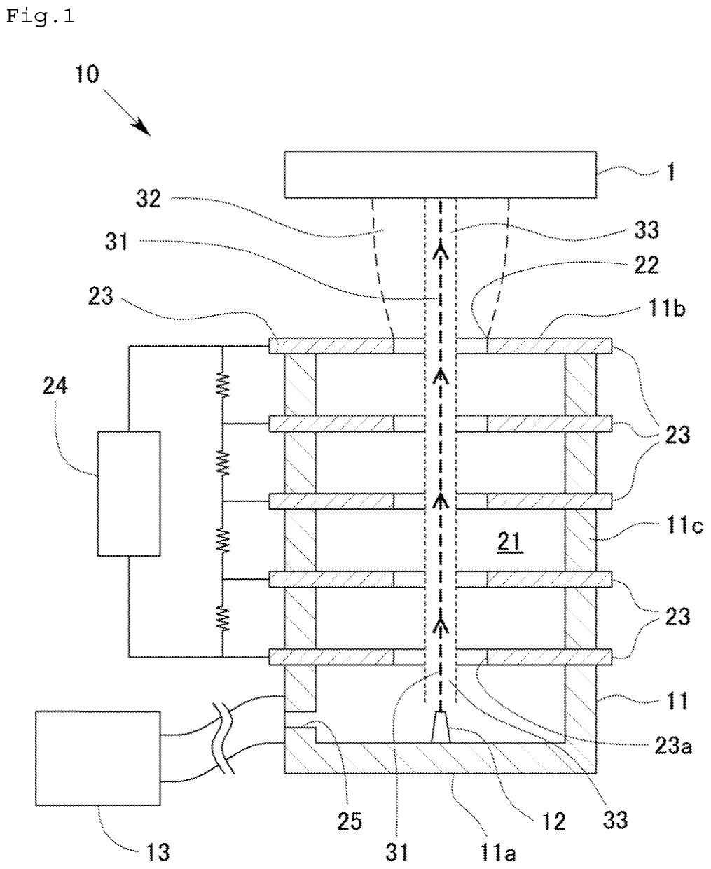

FIGS. 1 to 3 illustrate an electron beam irradiation device according to embodiments of the present invention.

As illustrated in FIG. 1, the electron beam irradiation device 10 includes an acceleration tube 11, an electron gun 12 and hydrogen gas supply means 13.

The acceleration tube 11 has a cylindrical shape and includes an acceleration space 21. One end surface 11a of the acceleration tube 11 is closed. Another end surface 11b of the acceleration tube 11 is provided with an irradiation port 22 at the center of the surface. The acceleration tube 11 includes a plurality of electrodes 23 disposed at substantially equal intervals in the length direction of the acceleration tube 11 so as to protrude from an external side surface of the acceleration tube 11 toward the acceleration space 21 through a side wall 11c. The acceleration tube 11 also includes a high voltage power supply 24 connected to each electrode 23. Each of the electrodes 23 has an annular shape with a hole 23a formed at the center and is attached to the acceleration tube 11 such that the center axis of each electrode 23 is aligned with the center line that runs through the acceleration space 21. The high voltage power supply 24 is configured to apply voltage between pairs of adjacent electrodes 23 such that potential increases from electrodes 23 closer to the one end surface 11a to electrodes 23 closer to the other end surface 11b in the acceleration tube 11. The acceleration tube 11 also includes a gas supply port 25 on a side surface closer to the one end surface 11a. In the detailed example illustrated in FIG. 1, five electrodes 23 are provided.

The electrode gun 12 is disposed at the center of the one end surface 11a of the acceleration tube 11 on a side facing the acceleration space 21 and is configured to generate an electron beam toward the acceleration space 21. In the electron beam irradiation device 10, the high voltage power supply 24 applies voltage to each electrode 23 to accelerate the electron beam 31 generated by the electron gun 12 in the acceleration space 21. In other words, the electron beam irradiation device 10 is configured to accelerate the electron beam 31 using the difference in potential between electrodes 23 while the electron beam 31 travels toward the irradiation port 22 formed in the other end surface 11b through the hole 23a at the center of each electrode 23. The electron beam can also be irradiated to the outside through the irradiation port 22 in the electron beam irradiation device 10.

The hydrogen gas supply means 13 is connected to the gas supply port 25 in the acceleration tube 11 and can supply the acceleration space 21 with hydrogen gas at a predetermined pressure. For example, the hydrogen gas supply means 13 includes a hydrogen tank, a supply pipe connecting the hydrogen tank to the gas supply port 25, and a pump in the supply pipe so as to be able to pressurize and then supply the hydrogen gas to the acceleration space 21. Hydrogen gas has low density compared to other gases and only requires a small amount of energy to be ionized (13.6 eV per atom).

In the electron beam irradiation device 10, the hydrogen gas supply means 13 supplies the acceleration space 21 with hydrogen gas at a predetermined pressure, and the supplied hydrogen gas can be emitted from the irradiation port 22. As a result, the electron beam irradiation device 10 is configured such that the electron beam 31 irradiated from the irradiation port 22 passes through the hydrogen gas 32 emitted from the irradiation port 22.

Next, effects of the present invention are described.

In the electron beam irradiation device 10, among the hydrogen gas supplied to the acceleration space 21 by the hydrogen gas supply means 13, the electron beam 31 generated by the electron gun 12 and accelerated in the acceleration space 21 in the acceleration tube 11 can be used to successively ionize and make into plasma the hydrogen gas present at a portion through which the electron beam 31 passes. When this occurs, kinetic energy of the electron beam 31 is absorbed by ionization of the hydrogen gas and voltage is applied between the electrodes 23. Therefore, the electron beam 31 continues to accelerate. Produced plasma 33 is continuously irradiated with the electron beam 31 to heat the plasma 33. Therefore, under the same pressure, the plasma 33 can be expanded and density of the plasma 33 can be reduced. With this configuration, it is possible to reduce absorption of the kinetic energy of the electron beam 31 and lengthen the distance through which the electron beam can pass.

The same applies outside of the acceleration space 21. That is, in the electron beam irradiation device 10, the electron beam 31 passes through the hydrogen gas 32 emitted to the outside from the irradiation port 22, and hence the hydrogen gas 32 present where the electron beam 31 passed can be ionized and made into plasma. Therefore, the plasma 33 can be continuously irradiated with the electron beam 31 to heat and expand the plasma 33 and facilitate passage of the electron beam 31. With this configuration, the electron beam irradiation device 10 can irradiate the electron beam 31 toward an object 1 outside the irradiation port 22.

In the electron beam irradiation device 10, secondary electrons are generated when turning the hydrogen gas into plasma and these secondary electrons can also accelerate with the electron beam 31. Because hydrogen gas constantly flows ahead of the electron beam 31, a secondary electron avalanche occurs and the electron beam 31 can be irradiated with a large current. Protons generated when turning the hydrogen gas into plasma come into contact with each electrode 23 in the acceleration space 21 and the inner walls of the acceleration space 21 to receive electrons and return to the hydrogen gas.

The electron beam irradiation device 10 may further include magnetic field application means that can narrow, disperse and/or change direction of the electron beam 31 irradiated from the irradiation port 22. In an electron beam irradiation device 10 with this configuration, it is possible to control the electron beam 31 irradiated from the irradiation port 22 and effectively irradiate the object 1 with the electron beam 31.

The electron beam irradiation device 10 can also irradiate an object 1 placed in water with the electron beam 31. In other words, when the irradiation port 22 is placed in water, pressure of the hydrogen gas supplied to the acceleration space 21 by the hydrogen gas supply means 13 is set higher than or equal to the water pressure outside the irradiation port 22 such that the electron beam irradiation device 10 can emit hydrogen gas in water from the irradiation port 22. By emitting the hydrogen gas 32 toward the object 1 placed in water, the electron beam 31 passes through the hydrogen gas 32 and the object 1 can be irradiated with the electron beam 31. If the object 1 is a solid, the object 1 can be machined or welded. If the object 1 is a liquid, a gas or plasma, the object 1 can be ionized or heated.

If, for example, water pressure is at 100 atm and the pressure of the hydrogen gas is also at 100 atm, the density of the hydrogen gas is high (100 times the density at 1 atm). When the hydrogen gas is heated with the electron beam 31 from an ordinary temperature of approx. 300 K to 30,000 K, the volume V of the hydrogen gas increases 100 fold and the density of the hydrogen gas can be lowered to 1/100. As a result, travel of the electron beam can be facilitated even when using high-pressure hydrogen gas.

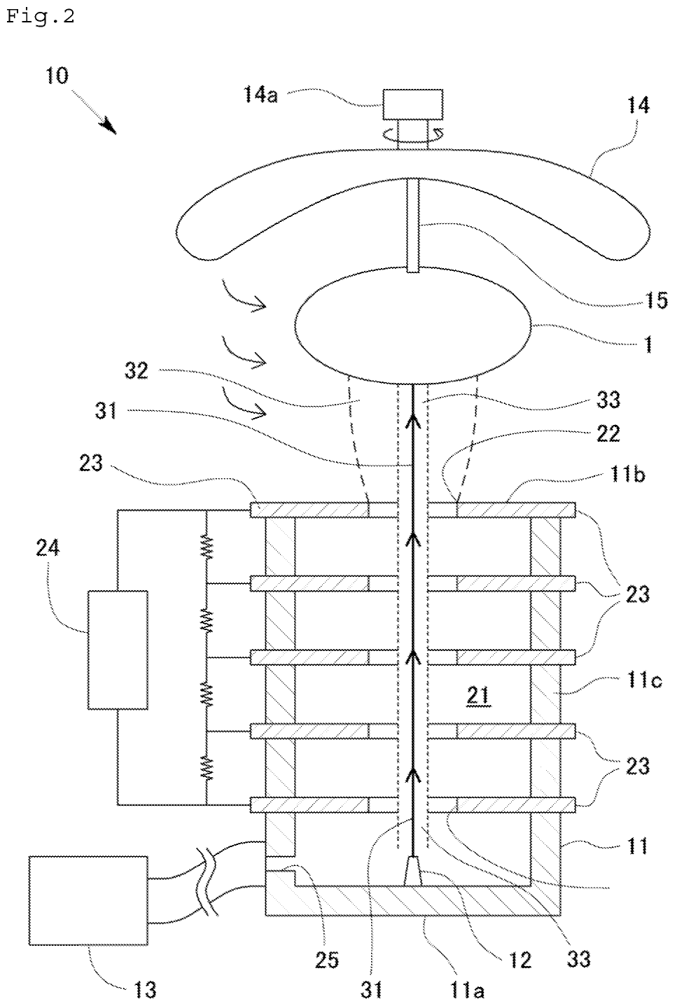

As illustrated in FIG. 2, electron beam irradiation device 10 may include current generating means 14 that can generate a current when the object 1 placed in water is a liquid, a gas or plasma. The current generated by the current generating means 14 may trap the object 1 at a predetermined position in the water. With this configuration, even an object 1 that is a liquid, a gas or plasma can be irradiated with the electron beam 31 without being dispersed in the water.

In the detailed example illustrated in FIG. 2, the current generating means 14 comprises a screw that generates a rotating current. The screw is rotated using a motor 14a such that a whirlpool can be generated about the center line of the acceleration space 21 on an outer side of the irradiation port 22. In this case, the object 1 can be trapped inside the whirlpool because pressure at the center of the whirlpool is lower than surrounding pressure. Note that, when irradiating with the electron beam 31, the hydrogen gas 32 also makes contact with the object 1 and is incorporated into the whirlpool, but the hydrogen gas can be elevated and absorbed using buoyancy by stopping the screw after irradiation with the electron beam 31 is complete.

As illustrated in FIG. 2, the electron beam irradiation device 10 may also include a supply/recovery tube 15 that can inject the object 1 toward a predetermined position in water and absorb the object 1 irradiated with the electron beam 31 from the predetermined position.

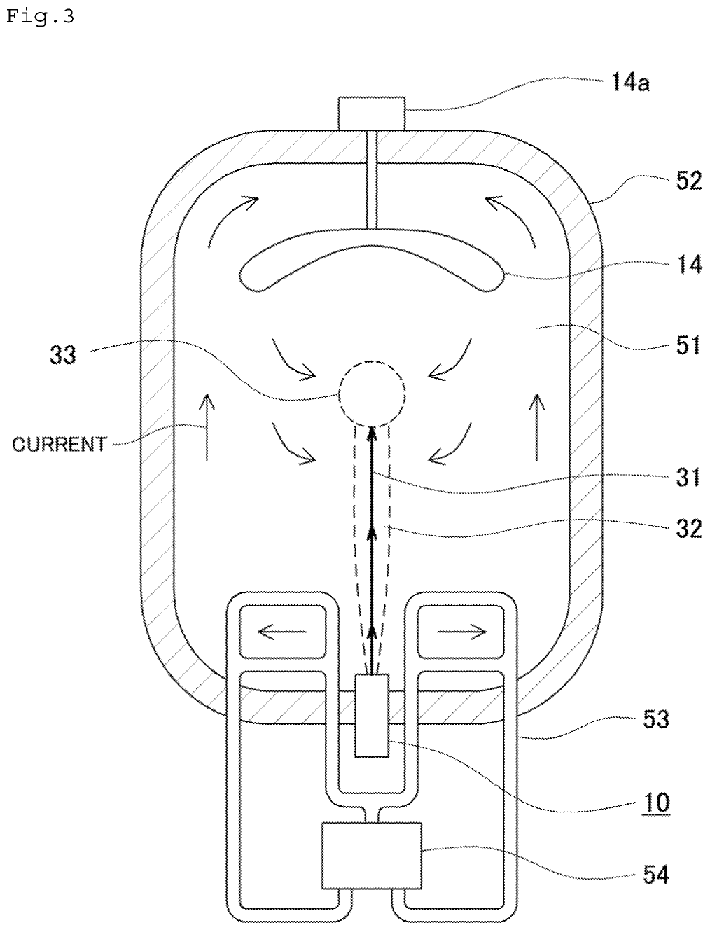

The electron beam irradiation device 10 can also be used for nuclear fusion power generation that employs supercritical water. More specifically, as illustrated in FIG. 3, hydrogen gas 32 comprising deuterium and tritium is injected into a pressurized container 52 filled with 500° C. supercritical water 51 with a pressure of 220 atm or greater. At the same time, the supercritical water 51 is irradiated as the object 1 with the electron beam 31 through the hydrogen gas 32. Through continuously irradiating the object 1 with the electron beam 31, water molecules and the deuterium and tritium mixed with the water molecules decompose and eventually become bare oxygen nuclei and protons, and deuterons, tritons and electrons. These charged particles cannot easily pass through water even at high speeds, but ionize and make into plasma the supercritical water 51 in the vicinity. As a result, the protons, deuterons and tritons that have collided with the bare oxygen nuclei generated in the vicinity of those particles bounce back without losing much kinetic energy. In addition, the bare oxygen nuclei involved in the collison stay in the vicinity without bouncing back and help the protons, deuterons and other particles bounce back.

The supercritical water 51 has low thermal conductivity of, for example, 0.1 W/mK. Therefore, the plasma 33, which consists of extremely dense hydrogen, deuterium and tritium, can be maintained at a high temperature for a long period of time by continuously irradiating a high-power electron beam 31 such that heat exceeding the amount of thermal diffusion can be generated using a sufficient amount of the supercritical water 51. Increasing the temperature of the plasma to approximately 30,000,000 K makes it possible to satisfy the self-ignition condition in a Lawson diagram and induce a D-T nuclear fusion reaction. When this occurs, the high-temperature plasma 33 and the discharged hydrogen gas 32 can be trapped at a predetermined position using a downstream current or whirlpool generated by the screw acting as the current generating means 14, and thermal energy resulting from nuclear fusion can be sent to a heat exchanger 53. The heat exchanger 53 absorbs this thermal energy to rotate a turbine 54 and thereby generate power.

### REFERENCE SIGNS LIST

1: Object
10: Electron beam irradiation device
11: Acceleration tube

11a: One end surface

11b: Other end surface

11c: Side wall

21: Acceleration space

22: Irradiation port

23: Electrode

23a: Hole

24: High voltage power supply

25: Gas supply port
12: Electron gun
13: Hydrogen gas supply means
14: Current generation means

14a: Motor
15: Supply/recovery tube
31: Electron beam
32: Hydrogen gas (emitted from irradiation port)
33: Plasma
51: Supercritical water
52: Pressurized container
53: Heat exchanger
54: Turbine

What is claimed is:

1. An electron beam irradiation device comprising:
an electron gun that generates an electron beam;
an acceleration tube including an acceleration space provided for accelerating the electron beam generated by the electron gun, and an irradiation port that can irradiate the electron beam accelerated in the acceleration space to the outside; and
hydrogen gas supply means configured to supply the acceleration space with hydrogen gas at a predetermined pressure,
wherein the hydrogen gas supplied to the acceleration space by the hydrogen gas supply means is emitted from the irradiation port, and the electron beam irradiated from the irradiation port passes through the hydrogen gas emitted from the irradiation port.

2. The electron beam irradiation device according to claim 1, wherein, when the irradiation port is placed in water, the hydrogen gas can be emitted toward an object placed at a predetermined position in the water and the object can be irradiated with the electron beam.

3. The electron beam irradiation device according to claim 2, further comprising:
current generation means configured to generate a current,
wherein the object is a liquid, a gas or plasma; and
wherein a current generated by the current generation means traps the object at the predetermined position in the water.
